(19) United States
(12) Patent Application Publication
(10) Pub. No.: US 2012/0074864 A1
(43) Pub. Date: Mar. 29, 2012

(54) METHOD AND CIRCUIT ARRANGEMENT FOR GENERATING A PULSED VOLTAGE

(75) Inventor: Ang Ding, Shanghai (CN)

(73) Assignee: KONINKLIJKE PHILIPS ELECTRONICS N.V., EINDHOVEN (NL)

(21) Appl. No.: 13/377,450

(22) PCT Filed: Jun. 8, 2010
(86) PCT No.: PCT/IB10/52524

§ 371 Date: Dec. 9, 2011

(30) Foreign Application Priority Data
Jun. 11, 2009 (CN) 200910145959.3

(51) Int. Cl. H05B 41/288; H03K 3/02

(52) U.S. Cl. 315/278; 307/106

(57) ABSTRACT

The invention proposes a circuit arrangement for converting a DC voltage from a DC power supply into a pulsed voltage to operate or drive a load, for example, a DBD lamp. The circuit arrangement comprises a transformer having a primary winding and a secondary winding, a first controllable switch branch, a second controllable switch branch, and a control unit. The control unit is configured to control the first controllable switch branch and the second controllable switch branch to be alternately turned on so that at least part of the energy from the DC power supply is stored in the primary winding during each turn-on period of the first controllable switch branch and the second controllable switch branch, and to leave an idle time between the two adjacent turn-on periods so that at least part of the stored energy is transferred to the secondary winding to alternately generate a positive pulsed voltage during one idle time and a negative pulsed voltage during the next idle time.

### FIELD OF THE INVENTION

The present invention relates to a circuit arrangement for, and a method of generating a pulsed voltage, more particularly, to a circuit arrangement for, and a method of generating a pulsed voltage from a DC power supply for the operation of a dielectric barrier discharge lamp.

### BACKGROUND OF THE INVENTION

A discharge generated within a discharge vessel which has a dielectric layer placed between at least one electrode and a discharge medium is known as a silent discharge, a quiet discharge, a dielectrically-impaired discharge, or a dielectric barrier discharge (referred to as “DBD”). This type of discharge with noble gas filling like xenon as the discharge medium in the discharge vessel is an interesting candidate for some special lighting applications. One application is widely used as DBD lamp for the production of vacuum ultraviolet (referred to as “VUV”) light. The special advantages of DBD lamps include immediate light production without a heating phase, constant light output and color temperature, no mercury, long lifetime, etc.

DBD lamps can be operated with continuous excitation or with pulsed excitation. It has been shown that pulsed operation in conjunction with a modified gas pressure leads to a significantly higher luminous efficiency of the lamp. For high-efficiency DBD lamps, pulsed operation is preferred, while continuous excitation is usually used in applications where the efficiency of the conversion of electric power into VUV light is not a primary goal. A classical and widely used topology to generate high-voltage pulses in the low-power range is the Flyback converter, which stores energy into a primary winding of a transformer and then feeds the energy to the lamp via a secondary winding of the transformer when the primary current is switched off. However, the existing Flyback converter is based on a uni-polar scheme that does not give optimum discharge.

### SUMMARY OF THE INVENTION

An object of the invention is to propose a circuit arrangement which is capable of converting a DC voltage from a DC power supply into a pulsed voltage, for example, for operating a discharge lamp.

A further object of the invention is to propose a method of converting a DC voltage from a DC power supply into a pulsed voltage.

In accordance with an aspect, the invention proposes a circuit arrangement for converting a DC voltage from a DC power supply into a pulsed voltage, for example to operate or drive a load, e.g. a dielectric barrier discharge lamp (herein referred to as “DBD lamp”). The circuit arrangement comprises a transformer, a first controllable switch branch, a second controllable switch branch and a control unit. The transformer comprises a primary winding and a secondary winding. The primary winding comprises a center tap, a first terminal and a second terminal. In one embodiment, the center tap is connected to the positive pole of the DC power supply and the secondary winding is intended to be connected to the load. The first controllable switch branch is coupled between the first terminal of the primary winding and the negative pole of the DC power supply. The second controllable switch branch is coupled between the second terminal of the primary winding and the negative pole of the DC power supply. The control unit is configured to control the first controllable switch branch and the second controllable switch branch in a manner including:
turning on the first controllable switch branch for a first period of time for charging the primary winding by the DC power supply;
turning off the first controllable switch branch for a second period of time for transferring energy stored in the primary winding to the secondary winding and generating a first pulsed voltage by the secondary winding;
turning on the second controllable switch branch for a third period of time for charging the primary winding by the DC power supply;
turning off the second controllable switch branch for a fourth period of time for transferring energy stored in the primary winding to the secondary winding and generating a second pulsed voltage with an inverse polarity relative to the first pulsed voltage by the secondary winding.

Thus, the circuit arrangement is capable of converting a DC voltage from a DC power supply into a bi-polar pulsed voltage. When the circuit arrangement operates one cycle by one cycle, then a bi-polar pulsed voltage sequence is produced in the secondary winding.

With two switch branches at the low voltage side of the transformer, the topology has almost all of the advantages of the conventional Flyback converter, such as simple structure, low cost and being suitable for a low input voltage. Additionally, the bi-polar pulsed voltage features high dV/dt and the negative voltage pulse gives optimum discharge when the bi-polar pulsed voltage sequence is used to operate a DBD lamp.

In accordance with another aspect of the invention proposes a method of converting a DC voltage from a DC power supply into a pulsed voltage, by using a circuit arrangement. The circuit arrangement comprises a transformer, a first controllable switch branch and a second controllable switch branch. The transformer has a primary winding with a center tap connected to the positive pole of the DC power supply and a secondary winding. The first controllable switch branch is coupled between a first terminal of the primary winding and the negative pole of the DC power supply. The second controllable switch branch is coupled between a second terminal of the primary winding and the negative pole of the DC power supply. The method comprises the steps of:
turning on the first controllable switch branch for a first period of time for charging the primary winding by the DC power supply;
turning off the first controllable switch branch for a second period of time for transferring energy stored in the primary winding to the secondary winding and generating a first pulsed voltage by the secondary winding;
turning on the second controllable switch branch for a third period of time for charging the primary winding by the DC power supply;
turning off the second controllable switch branch for a fourth period of time for transferring energy stored in the primary winding to the secondary winding and generating a second pulsed voltage with an inverse polarity relative to the first pulsed voltage by the secondary winding.

When the above steps are repeated, then a bi-polar pulsed voltage sequence, formed by multiple of the first and second pulsed voltage is attained.

### BRIEF DESCRIPTION OF THE DRAWINGS

The above and other objects and features of the invention will become apparent from the following detailed description of various exemplary embodiments with reference to the accompanying drawings, in which:

FIG. 1 is a schematic diagram of the circuit arrangement according to an exemplary embodiment of the invention;

FIG. 2 is a schematic diagram of switch driving signals and the pulsed output voltage of the exemplary circuit arrangement according to the invention;

FIG. 3 is a schematic diagram of the exemplary circuit arrangement at one operation state according to the invention;

FIG. 4 is an exemplary schematic diagram of the circuit arrangement at another operation state according to the invention.

### DETAILED DESCRIPTION OF EMBODIMENTS

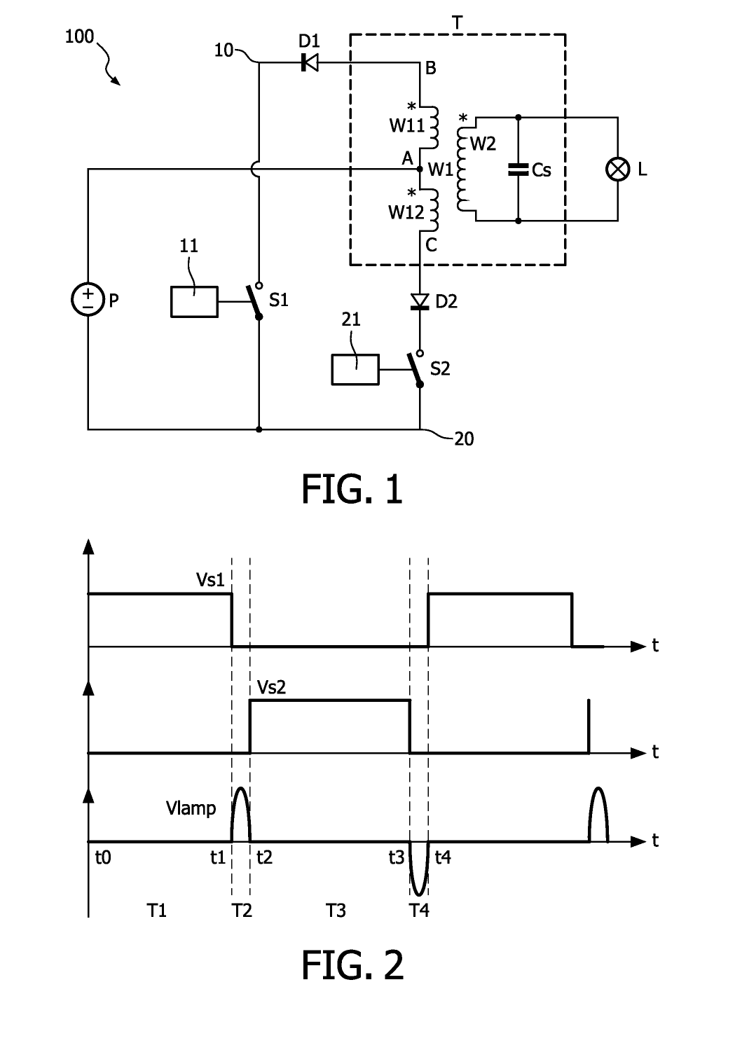

FIG. 1 is a schematic diagram of an exemplary circuit arrangement 100 according to the invention. The circuit arrangement 100 is designed to convert a DC voltage Vin from a DC power supply P into a pulsed voltage Vout for operation of a discharge lamp L. The discharge lamp L is designed for dielectric barrier discharge so as to generate ultraviolet light, and generally there is a dielectric layer placed between at least one electrode and a discharge medium in the lamp vessel. The actual design of the discharge lamp L is not decisive for an understanding of the circuit arrangement 100 or of the method, according to the exemplary embodiment of the invention.

The circuit arrangement 100 comprises a transformer T which has a primary winding W1 and a secondary winding W2. The primary winding W1 has a center tap A, a first terminal B and a second terminal C. Consequently, one sub-winding W11 is formed between the center tap A and the first terminal B and another sub-winding W12 is formed between the center tap A and the second terminal C. The center tap A is connected to the positive pole of the DC power supply P and the secondary winding W2 is connected to the electrodes of the discharge lamp L.

The circuit arrangement 100 further comprises a first controllable switch branch 10 and a second controllable switch branch 20. The first controllable switch branch 10 is coupled between the first terminal B of the primary winding W1 and the negative pole of the DC power supply P, while the second controllable switch branch 20 is coupled between the second terminal C of the primary winding W1 and the negative pole of the DC power supply P. As shown in FIG. 1, the first controllable switch branch 10 comprises a first switch S1 and a first diode D1 connected in series. The second controllable switch branch 20 comprises a second switch S2 and a second diode D2 connected in series. In an embodiment, the first switch S1 and the second switch S2 individually have a reverse parasitic diode. For example, when the switches are selected as MOSFET, then the first diode D1 and the second diode D2 are obligatory to avoid negative voltage brought on the first switch S1 and the second switch S2 by means of their reverse parasitic diodes, respectively. In another embodiment, the first switch S1 and the second switch S2 can tolerate negative voltages, for example when the switches are selected as solid state relay, then the first diode D1 and the second diode D2 are not needed.

The circuit arrangement 100 further comprises a first control unit 11 and a second control unit 21. The first control unit 11 is configured to control the first switch S1 to be turned on or off, for example via generating a first switch driving signal. The second control unit 21 is configured to control the second switch S2 to be turned on or off, for example via generating a second switch driving signal. Alternatively, the first control unit 11 and the second control unit 21 can be combined as one control unit to implement the same function.

FIG. 2 is a schematic diagram of the first and second switch driving signals and the pulsed output voltage of the circuit arrangement 100. The working duty cycle of the circuit arrangement 100 is defined such that each of the two switches S1 and S2 turns on and off once, meanwhile one positive voltage pulse and one negative voltage pulse are alternately generated during the period in which the two switches S1 and S2 turning off. For clarifying the operation principle of the circuit arrangement 100, the evolution of the equivalent circuit of the circuit arrangement 100 for a given duty cycle is broken down into four states, as depicted below.

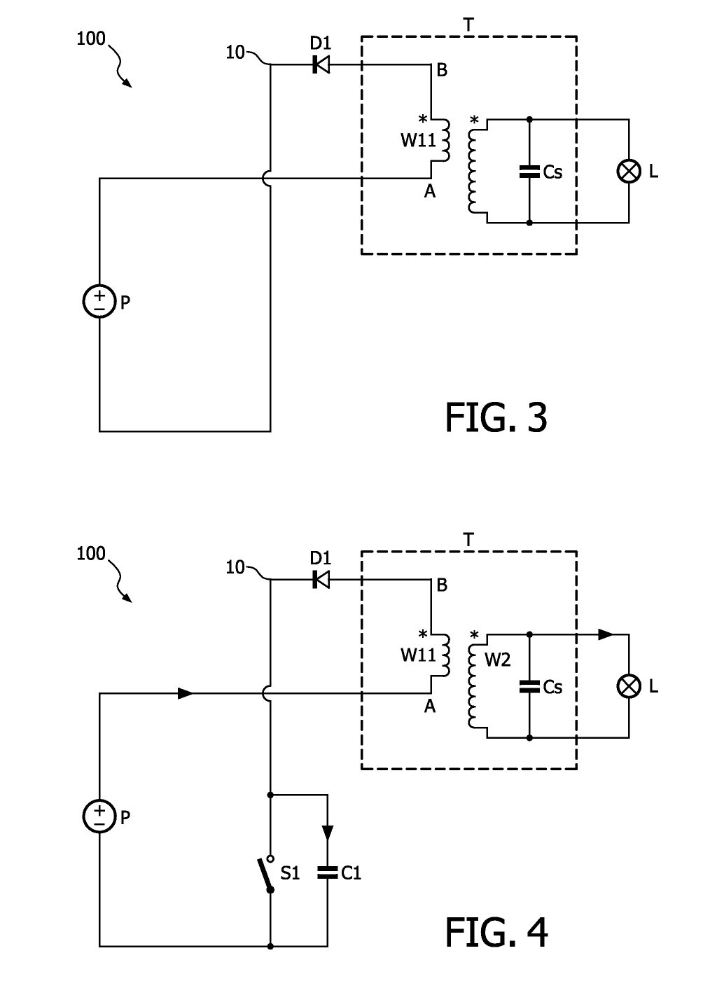

During a first period T1, from time t0 to t1, the first control unit 11 generates a first switch driving signal Vs1 to control the first switch S1 to be turned on, while the second switch S2 is turned off. The equivalent circuit of the circuit arrangement 100 in this first state is shown as FIG. 3. The first diode D1 conducts so that the DC power supply P and the first sub-winding W11 between the center tap A and the first terminal B form a closed loop. The voltage at the first terminal B can be deemed to be 0 V, while the voltage at the center tap A can be deemed to be equal to Vin. The first sub-winding W11 is charged and obtains energy from the DC power supply P.

During a second period T2, from time t1 to t2, the first switch S1 and the second switch S2 are both turned off. The equivalent circuit of the circuit arrangement 100 in this second state is shown as FIG. 4. The exciting current of the first sub-winding W11 starts to charge the parasitic capacitance C1 of the first switch S1. At the same time at least part of the energy stored in the primary winding W1 of the transformer T is transferred to the secondary winding W2. Consequently the secondary winding W2 of the transformer T attains an induced current, and a first voltage pulse, for example with a shape of a rough half-sinusoid and with a positive polarity, namely an induced voltage, is generated at the two output terminals of the secondary winding W2. The first voltage pulse induces the discharge medium to discharge inside the lamp vessel. When the exciting current falls to zero, the first voltage pulse reaches the peak value and then begins to decrease. When the first voltage pulse goes to almost zero, the second state ends.

In the second state, the voltage at the first terminal B becomes positive, while the voltage at the second terminal C becomes negative. If the second switch S2 has the reverse parasitic diode (not shown in the drawings), then the reverse parasitic diode will conduct. In this situation, although the second switch S2 is turned off, a close loop can also be formed by the reverse parasitic diode and result in the voltage at the second terminal C being clamped to a rather low value, which will limit an induced voltage of the first sub-winding W11 to reach a rather high level. Further, the induced voltage generated at the two output terminals of the secondary winding W2 may be accordingly at a low level. Thanks to the second diode D2, such a close loop cannot be formed by means of the reverse parasitic diode. Therefore, the induced voltage of the first sub-winding W11 can reach hundreds of volts and accordingly the peak value of the first voltage pulse can reach thousands of volts to meet the ignition requirement of the lamp L.

During a third period T3, from time t2 to t3, the second control unit 21 generates a second switch driving signal Vs2 to control the second switch S2 to be turned on, while the first switch S1 is turned off. The sub-winding W12 is charged and obtains energy from the DC power supply P.

During a fourth period T4, from time t3 to t4, the first switch S1 and the second switch S2 are both turned off. A second voltage pulse with an inverse polarity relative to the first voltage pulse, namely with a negative polarity, is generated at the two output terminals of the secondary winding W2, namely, generated in the secondary winding.

The third and fourth states are exactly the opposites of the first and second states, so a detailed description is not repeated.

If the circuit arrangement 100 operates for a plurality of cycles, then a pulsed voltage sequence, formed by a plurality of first voltage pulses and second voltage pulses, can be attained. Consequently, the first controllable switch branch 10 and the second controllable switch branch 20 are alternately turned on so that at least part of the energy from the DC power supply P is stored in the primary winding W1 and during each of the idle periods T2 and T4 between the two adjacent turn-on periods of the first controllable switch branch 10 and the second controllable switch branch 20 at least part of the stored energy is transferred to the secondary winding W2 to generate voltage pulses. Therefore, a bi-polar pulsed voltage sequence is generated in the secondary winding W2.

Alternatively stated, the first switch driving signal and the second switch driving signal have an approximately equal switching period with an approximately 180° phase difference. That is to say T1 is approximately equal to T3. Alternatively, T2 is approximately equal to T4. The idle times T2 and T4 are determined by an oscillating period of an oscillating circuit which is formed by the parasitic capacitance and the excitation inductance of the transformer T, as well as the lamp-inherent capacitance. The oscillating period is approximately equal to two times of the idle time, that is, the second period T2 is approximately equal to the fourth period T4 and approximately equal to half the oscillating period. Due to the symmetric driving of the two switches S1 and S2, the transformer T is intrinsically voltage balanced.

Typically, the DC voltage Vin is about tens of volts, for example 12 V, and the peak value of the pulsed voltage Vout may be a few kilovolts, for example 5 kV. The values of T1 (or T3) and T2 (or T4) are in the microsecond range and normally T2 (or T4) is markedly shorter than T1 (or T3). Therefore, the bi-polar pulsed voltage sequences feature high dV/dt. For DBD lamps, such a high rise rate of the pulsed voltage brings benefit to achieve high light output efficiency.

In the context, the term “approximately” means there may be a tolerance when a comparison is made between two or more objectives and such a tolerance is acceptable in the related technical field of the objectives.

The embodiments described above are merely exemplary embodiments of the invention. Other variations of the disclosed embodiments can be understood and effected by those skilled in the art in practicing the claimed invention, from a study of the drawings, the disclosure, and the appended claims. These variations shall also be considered to be within the scope of the present invention. In the claims and description, use of the verb “comprise” and its conjugations does not exclude other elements or steps, and the indefinite article “a” or “an” does not exclude a plurality.

1. A circuit arrangement (100) for converting a DC voltage from a DC power supply (P) into a pulsed voltage, the circuit arrangement (100) comprising:
a transformer (T) comprising a primary winding (W1) and a secondary winding (W2), the primary winding (W1) comprising a center tap (A), a first terminal (B), and a second terminal (C), the center tap (A) being connected to the positive pole of the DC power supply (P), and the secondary winding (W2) being connected to a load (L);
a first controllable switch branch (10) coupled between the first terminal (B) of the primary winding (W1) and the negative pole of the DC power supply (P);
a second controllable switch branch (20) coupled between the second terminal (C) of the primary winding (W1) and the negative pole of the DC power supply (P); and
a control unit (11, 21) configured to control the first controllable switch branch (10) and the second controllable switch branch (20) in a manner including:
turning on the first controllable switch branch (10) for a first period of time (T1) for charging the primary winding (W1) by the DC power supply (P);
turning off the first controllable switch branch (10) for a second period of time (T2) for transferring energy stored in the primary winding (W1) to the secondary winding (W2) and generating a first pulsed voltage by the secondary winding (W2);
turning on the second controllable switch branch (20) for a third period of time (T3) for charging the primary winding (W1) by the DC power supply (P); and
turning off the second controllable switch branch (20) for a fourth period of time (T4) for transferring energy stored in the primary winding (W1) to the secondary winding (W2) and generating a second pulsed voltage with an inverse polarity relative to the first pulsed voltage by the secondary winding (W2).

2. The circuit arrangement (100) according to claim 1, wherein the control unit (11, 21) is configured to generate a first switch driving signal and a second switch driving signal for controlling the first controllable switch branch (10) and the second controllable switch branch (20), respectively, the first switch driving signal and the second switch driving signal having an approximately equal switching period and having an approximately 180° phase difference.

3. The circuit arrangement (100) according to claim 1, wherein the second period (T2) is approximately equal to the fourth period (T4) and approximately equal to half an oscillating period of an oscillating circuit formed by a parasitic capacitance (Cs) and an excitation inductance inherent to the transformer (T) and an inherent capacitance of the load (L).

4. The circuit arrangement (100) according to claim 1, wherein the first controllable switch branch (10) comprises a solid state relay.

5. The circuit arrangement (100) according to claim 1, wherein the first controllable switch branch (10) comprises a MOSFET switch (S1) and a diode (D1) connected in series.

6. The circuit arrangement (100) according to claim 1, wherein the second controllable switch branch (20) comprises a solid state relay.

7. The circuit arrangement (100) according to claim 1, wherein the second controllable switch branch (20) comprises a MOSFET switch (S2) and a diode (D2) connected in series.

8. A lighting system comprising the circuit arrangement (100) according to claim 1, and a dielectric barrier discharge lamp used as the load (L).

9. A method of converting a DC voltage from a DC power supply (P) into a pulsed voltage, by using a circuit arrangement (100) comprising a transformer (T) having a primary winding (W1) with a center tap (A) connected to the positive pole of the DC power supply (P) and a secondary winding (W2), a first controllable switch branch (10) coupled between a first terminal (B) of the primary winding (W1) and the negative pole of the DC power supply (P), and a second controllable switch branch (20) coupled between a second terminal (C) of the primary winding (W1) and the negative pole of the DC power supply (P), the method comprising the steps of:
turning on the first controllable switch branch (10) for a first period of time (T1) for charging the primary winding (W1) by the DC power supply (P);
turning off the first controllable switch branch (10) for a second period of time (T2) for transferring energy stored in the primary winding (W1) to the secondary winding (W2) and generating a first pulsed voltage by the secondary winding (W2);
turning on the second controllable switch branch (20) for a third period of time (T3) for charging the primary winding (W1) by the DC power supply (P);
turning off the second controllable switch branch (20) for a fourth period of time (T4) for transferring energy stored in the primary winding (W1) to the secondary winding (W2) and generating a second pulsed voltage with an inverse polarity relative to the first pulsed voltage by the secondary winding (W2).

10. The method according to claim 9, wherein the first period (T1) is approximately equal to the third period (T3).

11. The method according to claim 9, wherein the second period (T2) is approximately equal to the fourth period (T4) and approximately equal to half an oscillating period of an oscillating circuit formed by a parasitic capacitance (Cs) and an excitation inductance inherent to the transformer (T) and an inherent capacitance of an electronic load (L) to which the pulsed voltage is provided.
